(19) United States
(12) Patent Application Publication
(10) Pub. No.: US 2023/0179922 A1
(43) Pub. Date: Jun. 8, 2023

(54) Flexible circuit board and speaker using same

(71) Applicant: AAC Microtech (Changzhou) Co., Ltd., Changzhou City (CN)

(72) Inventors: Wei Song, Shenzhen (CN); Xin Jin, Shenzhen (CN); Ronglin Linghu, Shenzhen (CN)

(21) Appl. No.: 17/566,701

(22) Filed: Dec. 31, 2021

(30) Foreign Application Priority Data
Dec. 2, 2021 (CN) 202123024488.6

(51) Int. Cl. H04R 9/06; H05K 1/02; H05K 1/09; H04R 1/02; H04R 9/02; H04R 3/00; H04R 9/04; H04R 7/18; H04R 7/12

(52) U.S. Cl. CPC H04R 9/06; H05K 1/028; H05K 1/09; H04R 1/025; H04R 9/025; H04R 3/00; H04R 9/045; H04R 7/18; H04R 7/12; H05K 2201/0154; H05K 2201/0355; H05K 2201/10083; H04R 2400/11

(57) ABSTRACT

The present disclosure discloses a flexible circuit board and a speaker. The flexible circuit includes a substrate, a first cover film attached to a side of the substrate and including at least a silica gel layer, a second cover film attached to the other side of the substrate, and a copper foil layer sealed between the substrate and the first cover film or between the substrate and the second cover film. Compared with the related art, the flexible circuit disclosed by the present disclosure has a higher strength.

### FIELD OF THE PRESENT DISCLOSURE

The present disclosure relates to electroacoustic transducers, in particular to a flexible circuit board and a speaker.

### DESCRIPTION OF RELATED ART

A flexible circuit board serves as a part of a speaker's vibration system and conduction circuit at the same time, and is subjected to the dual effects of temperature and vibration stress during the working process. A copper foil layer on one side of a substrate can be etched to form conductive lines as needed, and a covering film is pasted on a surface of the copper foil layer to protect the copper foil layer from breaking due to vibration and deformation; the other side of the substrate can be attached with the covering film as needed, in order to adjust an elastic arm stiffness of the flexible circuit board and the stress on the metal conductive layer during vibration.

The conventional cover film is usually composed of an adhesive layer on an inside and a polyimide layer on an outside, and the adhesive in the cover film is mostly epoxy resin adhesive or acrylic adhesive, the adhesive layer ages as the temperature rises. For the flexible circuit boards subjected to continuous vibration, this type of the cover film cannot provide sufficient protection for the copper foil layer, and it is prone to phenomena such as separation of the adhesive layer and the copper layer, copper foil cracks, and circuit breakage.

Therefore, it is necessary to provide a flexible circuit board and speaker that can continuously and effectively protect the metal conductive layer under working conditions.

### SUMMARY

An objective of the present disclosure is to provide a flexible circuit board which has a higher strength.

In order to achieve the objective mentioned above, the present disclosure discloses a flexible circuit board including a substrate, a first cover film attached to a side of the substrate and including at least a silica gel layer, a second cover film attached to the other side of the substrate, and a copper foil layer sealed between the substrate and the first cover film or between the substrate and the second cover film.

Further, the first cover film includes a first polyimide film attached to a side of the silica gel layer away from the substrate.

Further, the second cover film includes a second polyimide film and an adhesive layer, the second polyimide film is fixed to the substrate via the adhesive layer.

Further, the copper foil layer is embedded in the adhesive layer when the copper foil layer is located between the substrate and the second cover film.

Further, the copper foil layer is embedded in the silica gel layer when the copper foil layer is located between the substrate and the first cover film.

Further, the substrate is made of thermosetting polyimide or thermoplastic polyimide.

The present disclosure discloses a speaker including a holder with a receiving cavity, a magnetic circuit system located in the receiving cavity, and a vibration system located in the receiving cavity. The vibration system includes an upper diaphragm fixed to an upper end of the holder, a vibration frame fixed to the upper diaphragm, the flexible circuit board as described above, a voice coil fixed to the vibration frame and driving the upper diaphragm to vibrate and emit sound, the voice coil connected to an external circuit via the flexible circuit board, and a lower diaphragm fixed to the flexible circuit board. One end of the flexible circuit board is fixed to the holder, and the other end is fixed to the vibration frame.

Further, the magnetic circuit system includes a bottom plate fixed to a side of the holder away from the upper diaphragm, a main magnet arranged on the bottom plate, and a secondary magnetic component separated from the main magnetic and formed a magnetic gap with the main magnet. The secondary magnetic component is arranged around the main magnet, the voice coil is suspended in the magnetic gap by the vibration frame.

Further, the flexible circuit board includes a first fixing part fixed to the holder, a second fixing part spaced apart from the first fixing part, and an elastic arm connecting the first fixing part and the second fixing part, the second fixing part is fixed to a side of the vibration frame away from the upper diaphragm.

### BRIEF DESCRIPTION OF THE DRAWINGS

Many aspects of the embodiments can be better understood with reference to the following drawings. The components in the drawing are not necessarily drawn to scale, the emphasis instead being placed upon clearly illustrating the principles of the present disclosure.

FIG. 1 is a schematic diaphragm of a layer structure of a flexible circuit board in accordance with a first embodiment of the present disclosure;

FIG. 2 is a schematic diaphragm of a layer structure of a flexible circuit board in accordance with a second embodiment of the present disclosure;

FIG. 3 is a schematic diaphragm of a layer structure of a flexible circuit board in accordance with a third embodiment of the present disclosure;

FIG. 4 is a schematic diaphragm of a layer structure of a flexible circuit board in accordance with a fourth embodiment of the present disclosure;

FIG. 5 is an isometric view of a speaker after being assembled according to the embodiments of the present disclosure;

FIG. 6 is a cross-sectional view taken along a line A-A of FIG. 5;

FIG. 7 is an exploded view of the speaker in FIG. 5;

FIG. 8 is an isometric view of an internal assembly of the speaker in FIG. 5;

FIG. 9 is an isometric view of the flexible circuit board of the speaker in FIG. 5.

### DETAILED DESCRIPTION OF THE EMBODIMENTS

The present disclosure will hereinafter be described in detail with reference to the embodiments. To make the technical problems to be solved, and technical solutions and beneficial effects of the present disclosure more apparent, the present disclosure is described in further detail together with the figures and the embodiments. It should be understood the embodiments described hereby are only to explain the disclosure, not intended to limit the disclosure.

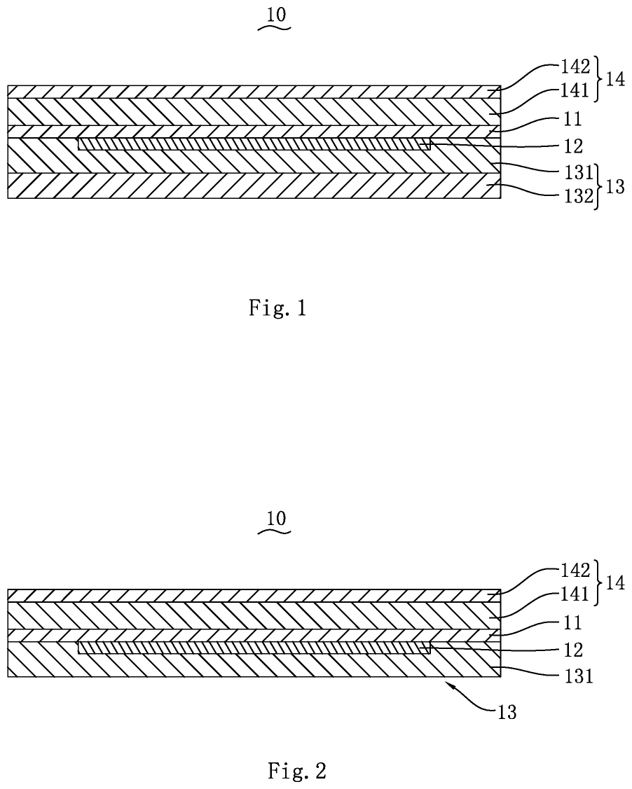

Referring to FIGS. 1-4, the present disclosure discloses a flexible circuit board 10 used in a speaker. The flexible circuit board 10 includes a substrate 11, a first cover film 13 attached on a side of the substrate 11, a second cover film 14 attached to the other side of the substrate 11, and a copper foil layer 12 sealed between the substrate 11 and the first cover film 13 or between the substrate 11 and the second film 14. The first cover film 13 at least includes a silica gel layer 131. Further, in the present embodiment, the second cover film 14 includes a second polyimide film 142 and an adhesive layer 141, the second polyimide film 142 is fixed to the substrate 11 via the adhesive layer 141.

In this embodiment, a conductive circuit is made of a single-layer copper foil layer 12. Compared with the prior art adopting a double-layer copper foil layer and implementing a conductive structure via metallized through holes, the tensile strength of the flexible circuit board 10 is improved, the service life is prolonged, the structure is simple, and the cost is saved. In conjunction with the structure that the silica gel layer 131 is arranged on a side of the substrate close to the silica layer or a side of the substrate away from the silica gel layer, during the working process of the speaker (generally temperature<150° C.), the physical change of the silica gel is little to provide sustainable and effective protection, the circuit in the copper foil layer 12 can increase supportability and reduce expansion and contraction, thereby increasing the strength of the entire flexible circuit board 10, and reducing the occurrence of copper foil cracks, circuit breaks and so on; further, according to the needs of the vibration system of the speaker, the material, thickness and parameters of the silica gel layer 131 can be adjusted to effectively adjust the stiffness of the vibration system to increase the freedom of speaker performance tuning.

It should be noted that the substrate 11 in the present invention is made of thermosetting polyimide, or may be made of thermoplastic polyimide, and the present invention does not make special restrictions on the material of the substrate.

In a first embodiment, referring to FIG. 1, the first embodiment discloses that the flexible circuit board 10 includes a substrate 11, the first cover film 13 attached on a side of the substrate 11, a second cover film 14 attached to the other side of the substrate 11, and a copper foil layer 12 sealed between the substrate 11 and the first cover film 13. In the first embodiment, the first cover film 13 further includes a silica gel layer 131 and a first polyimide film 132 attached to a side of the silica gel layer 131 away from the substrate 11, the silica gel layer 131 and the first polyimide film 132 are deposited on a side close to the copper foil layer 12 to wrap the copper foil layer 12.

Thus, the silica gel layer 131 is located on the side of the substrate 11 close to the copper foil layer, the copper foil layer 12 is embedded in the silica gel layer 131, so that the copper foil layer 12 is wrapped and protected by the silica gel layer 131, the physical change of the silica gel layer is small to provide sustainable and effective wrapping of the copper foil layer, thereby reducing the risk of tearing, breaking and other defects due to deformation of the copper foil layer during vibration. Further, according to the needs of the vibration system of the speaker, the material of the silica gel layer 131 can be adjusted to effectively adjust the stiffness of the vibration system to increase the freedom of speaker performance tuning.

In a second embodiment, referring to FIG. 2, the difference between the flexible circuit board 10 provided by the second embodiment of the present invention and the first embodiment shown in FIG. 1 is that, a first covering film 13 in this embodiment only includes a silica gel layer 131, and the first polyimide layer 132 is omitted. Thus, the structure of the flexible circuit board 10 is simpler, the manufacturing process of the flexible circuit board 10 can be simplified, the cost can be reduced; and compared with the first embodiment shown in FIG. 1, the thickness of the silica gel layer 131 can meet the rigidity requirements of the vibration system in different intervals.

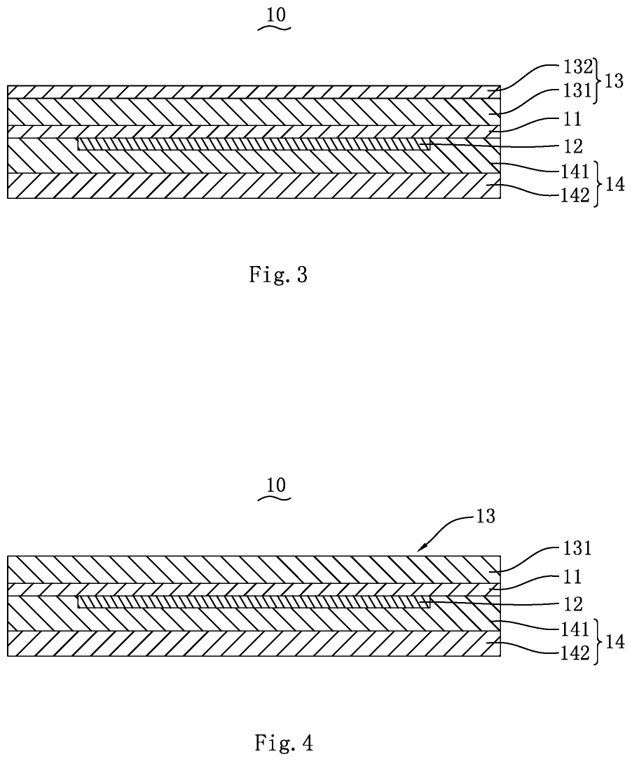

In a third embodiment, referring to FIG. 3, the third embodiment discloses that a flexible circuit board 10 includes a substrate 11, a first cover film 13 attached on a side of the substrate 11, a second cover film 14 attached to the other side of the substrate 11, and a copper foil layer 12 sealed between the substrate 11 and second cover film 14. In the third embodiment, the second cover film 14 further includes a second polyimide film 142 and an adhesive layer 141. The second polyimide layer 142 is bonded and fixed to the substrate 11 through the adhesive layer 141, and the copper foil layer 12 is embedded in the adhesive layer 141, so that the copper foil layer 12 is wrapped and protected by the adhesive layer 141; the adhesive layer 141 can use epoxy resin adhesive or acrylic adhesive.

In the third embodiment, the first cover film 13 includes a silica gel layer 131 and a first polyimide film 132 attached to the side of the silica gel layer 131 away from the substrate 11. The use of the silica gel layer 131 can help reduce the stiffness of the elastic arm 17 of the flexible circuit board 10, reduce the stress on the copper foil circuit, and improve the reliability and service life of the vibration state.

In a fourth embodiment, referring to FIG. 4, the difference between the flexible circuit board 10 provided by the fourth embodiment of the present invention and the first embodiment shown in FIG. 1 is that, a first covering film 13 in this embodiment only includes a silicone layer 131, and the first polyimide layer 132 is omitted. Thus, the structure of the flexible circuit board 10 is simpler, the manufacturing process of the flexible circuit board 10 can be simplified, the cost can be reduced; and it takes up less space to achieve the same level of reliability and service life.

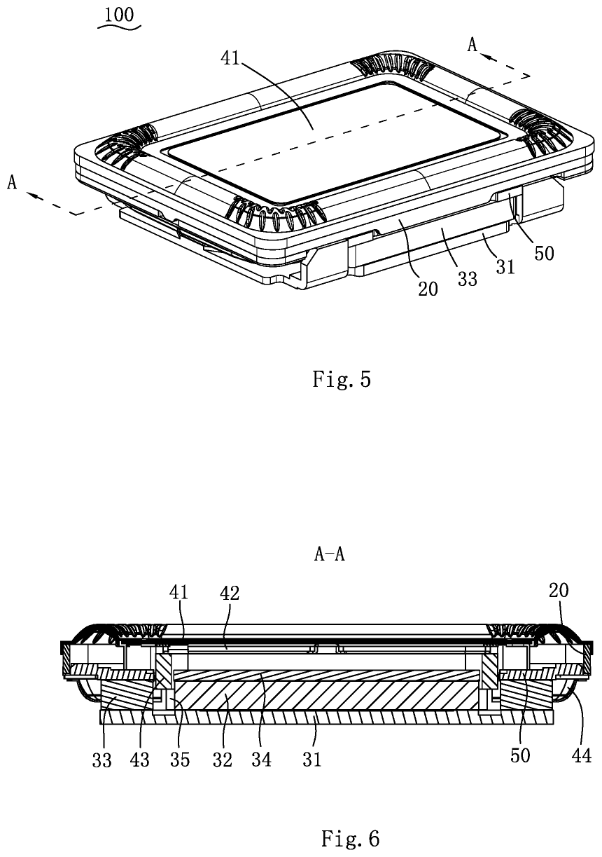

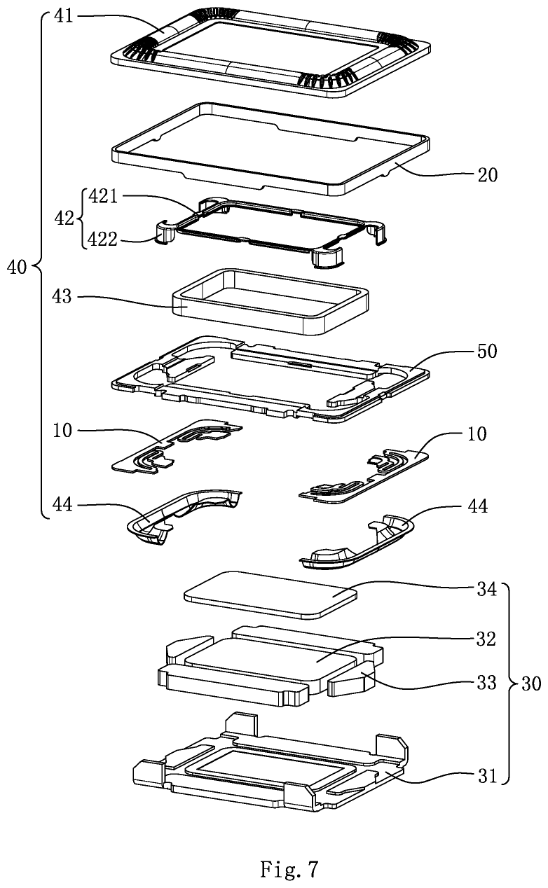

Referring to FIGS. 5-7, the present disclosure further discloses a speaker 100 including a holder 20 with a receiving cavity, and a magnetic circuit 30 system and a vibration system 40 located in the receiving cavity. The vibration system 40 includes an upper diaphragm 41, a vibration frame 42, a voice coil 43, a lower diaphragm 44 and a flexible circuit board 10. The specific structure of the flexible circuit board 10 refers to the above-mentioned embodiments. Since the speaker 100 can adopt all the technical solutions of all the foregoing embodiments, it has at least all the beneficial effects brought about by the technical solutions of the foregoing embodiments, which will not be repeated here.

In addition, the upper diaphragm 41 is fixed to an upper end of the holder 20, the vibration frame 42 is fixed to a lower end of the upper diaphragm 41, the voice coil 43 is fixed to the vibration frame 42 and drives the upper diaphragm 41 to vibrate and emit sound. The lower diaphragm 44 is fixed to the flexible circuit board 10, one end of the flexible circuit board 10 is fixed to the holder 20, and the other end of flexible circuit board 10 is fixed to the vibration frame 42. The voice coil 43 is connected to the external circuit via the flexible circuit board 10.

Further, the speaker 100 includes a skeleton 50 fixed to a bottom of the holder 20. The magnetic circuit system 30 includes a bottom plate 31, a main magnet 32 arranged on the bottom plate 31, and a secondary magnetic component 33 separated from the main magnetic 32 and formed a magnetic gap 35 with the main magnet 32, the bottom plate 31 is fixedly connected to the skeleton 50 so as to achieve relative fixation with the holder 20, the secondary magnetic component 33 is arranged around the main magnet 32, the voice coil 43 is suspended in the magnetic gap 35 by the vibration frame 42.

It should be noted that, the speaker 100 further includes a pole plate 34 which is fixed to a side of the main magnet 32 away from the bottom plate 31. In addition, the bottom plate 31, the skeleton 50 and the pole plate 34 are all made of magnetically permeable materials, the material of the upper diaphragm 41 and the lower diaphragm 44 is a polymer material, and the polymer material is silica gel, rubber, polyether ether ketone or thermoplastic Polyurethane elastomer rubber and so on.

In this embodiment, the shape of the voice coil 43 is a racetrack shape, but may also be other ring structures. Correspondingly, the vibrating frame 42 includes a racetrack-shaped main body portion 421. A top surface of the main body portion 421 is fixedly connected to the upper diaphragm 41, and a bottom surface is fixedly connected to the voice coil 43, thus the voice coil 43 is suspended in the magnetic gap 35.

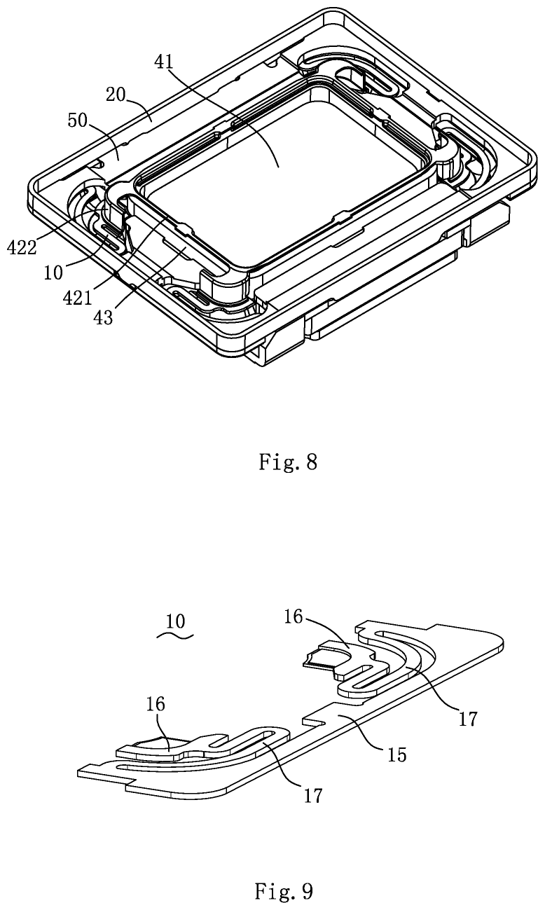

As shown in FIG. 8 and FIG. 9, the vibrating frame 42 further includes connecting portions 422 respectively formed at the four corners of the main body portion 421, and the four connecting portions 422 are located outside the voice coil 43. In this embodiment, the number of the flexible circuit boards 10 is two, which are respectively arranged at both ends of the speaker 100 in a longitudinal direction. Each flexible circuit board 10 includes a first fixing portion 15, two second fixing portions 16 spaced apart from the first fixing portion 15, and an elastic arm 17 formed between the second fixing portion 16 and the first fixing portion 15. The first fixing portion 15 is fixed to the skeleton 50, and a total of four second fixing portions 16 of the two flexible circuit boards 10 are respectively fixed to the bottom surfaces of the four connecting portions 422 of the vibration frame 42.

Thus, the upper diaphragm 41 is respectively connected to the voice coil 43 and the flexible circuit board 10 via the vibration frame 42. Compared with the structure in which the voice coil 43 is directly connected to the flexible circuit board 10 in the prior art, the speaker 100 of this embodiment can reduce the stress on the flexible circuit board 10 and improve the reliability of the speaker 100 in a vibration state and the service life of the flexible circuit board 10.

It is to be understood, however, that even though numerous characteristics and advantages of the embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms where the appended claims are expressed.

What is claimed is:

1. A flexible circuit board, comprising:
a substrate;
a first cover film attached to a side of the substrate and including at least a silica gel layer;
a second cover film attached to the other side of the substrate; and
a copper foil layer sealed between the substrate and the first cover film or between the substrate and the second cover film.

2. The flexible circuit board as described in claim 1, wherein the first cover film comprises a first polyimide film attached to a side of the silica gel layer away from the substrate.

3. The flexible circuit board as described in claim 1, wherein the second cover film comprises a second polyimide film and an adhesive layer, the second polyimide film is fixed to the substrate via the adhesive layer.

4. The flexible circuit board as described in claim 3, wherein the copper foil layer is embedded in the adhesive layer when the copper foil layer is located between the substrate and the second cover film.

5. The flexible circuit board as described in claim 1, wherein the copper foil layer is embedded in the silica gel layer when the copper foil layer is located between the substrate and the first cover film.

6. The flexible circuit board as described in claim 1, wherein the substrate is made of thermosetting polyimide or thermoplastic polyimide.

7. A speaker, comprising;
a holder with a receiving cavity;
a magnetic circuit system located in the receiving cavity; and
a vibration system located in the receiving cavity, comprising;
an upper diaphragm fixed to an upper end of the holder;
a vibration frame fixed to the upper diaphragm;
the flexible circuit board as described in claim 1, one end of the flexible circuit board fixed to the holder, and the other end fixed to the vibration frame;
a voice coil fixed to the vibration frame and driving the upper diaphragm to vibrate and emit sound, the voice coil connected to an external circuit via the flexible circuit board; and
a lower diaphragm fixed to the flexible circuit board.

8. The speaker as described in claim 7, wherein the magnetic circuit system comprises a bottom plate fixed to a side of the holder away from the upper diaphragm, a main magnet arranged on the bottom plate, and a secondary magnetic component separated from the main magnetic and formed a magnetic gap with the main magnet, the secondary magnetic component is arranged around the main magnet, the voice coil is suspended in the magnetic gap by the vibration frame.

9. The speaker as described in claim 7, wherein the flexible circuit board comprises a first fixing part fixed to the holder, a second fixing part spaced apart from the first fixing part, and an elastic arm connecting the first fixing part and the second fixing part, the second fixing part is fixed to a side of the vibration frame away from the upper diaphragm.
